(19) United States
(12) Patent Application Publication
(10) Pub. No.: US 2012/0199477 A1
(43) Pub. Date: Aug. 9, 2012

(54) FILM FORMING APPARATUS

(75) Inventor: Takahide UENOSONO, Tokyo (JP)

(73) Assignee: CANON ANELVA CORPORATION, Kawasaki-shi (JP)

(21) Appl. No.: 13/372,660

(22) Filed: Feb. 14, 2012

Related U.S. Application Data
(63) Continuation of application No. PCT/JP2010/064371, filed on Aug. 25, 2010.

(30) Foreign Application Priority Data
Aug. 26, 2009 (JP) 2009-194900

(51) Int. Cl. C23C 14/34

(52) U.S. Cl. 204/298.15

(57) ABSTRACT

The present invention provides a film forming apparatus that can reduce the adherence of thin film material particles to a holding mechanism included in a substrate tray at the time of film formation. In an embodiment of the present invention, a sputtering chamber includes the substrate tray that has bottom clamps and side clamps, a movement mechanism that changes the position of the side clamps between when the film is formed on the substrate and when the substrate is transferred and a mask that has an opening of a predetermined shape through which sputter particles from a cathode pass. At the time of transfer, the movement mechanism moves the side clamps such that the side clamps hold the substrate; at the time of film formation, the movement mechanism moves the side clamps toward the outside of the substrate tray.

### CROSS-REFERENCE TO RELATED APPLICATIONS

This application is a continuation of International Application No. PCT/JP2010/064371, filed Aug. 25, 2010, which claims the benefit of Japanese Patent Application No. 2009-194900, filed Aug. 26, 2009, both of which are hereby incorporated by reference herein in their entirety.

### BACKGROUND OF THE INVENTION

1. Field of the Invention

The present invention relates to a film forming apparatus, and more particularly relates to a film forming apparatus (for example, a vacuum processing apparatus) that uses a substrate tray used for the transfer of a substrate to perform predetermined processing.

2. Description of the Related Art

In the production of various display elements such as a liquid crystal display and a plasma display, it is necessary to perform processing such as film formation on an object to be processed (hereinafter referred to as a substrate). For example, in a liquid crystal display, it is necessary to perform processing of forming a transparent electrode and the like on a plate surface (the surface other than end surfaces) of a glass substrate.

In order to process a substrate under a predetermined atmosphere as proposed in Japanese Patent Application Laid-open No. 2003-147519, a film forming apparatus that is a vacuum processing apparatus used in such processing includes a process chamber which is configured so as to be evacuated into vacuum or such that a predetermined gas can be introduced inside. For example, if the film forming apparatus is a sputtering apparatus, the process chamber is a sputtering chamber or the like. Since it is necessary to, for example, continuously perform different types of processing and gradually decrease pressure from atmospheric pressure, the film forming apparatus is configured to include a plurality of process chambers, a load lock chamber and the like.

FIG. 4 shows a diagram showing the configuration of a sputtering chamber of a conventional sputtering apparatus among film forming apparatuses when seen from above. In FIG. 4, a load lock chamber or the like is omitted that transfers or carries out a glass substrate from the side of the atmosphere to the sputtering chamber 16.

In the sputtering chamber 16, for example, four triangular cathodes 23 are attached to each of the left and the right of the sputtering chamber 16, and a target 24 is attached as a thin film material source to each surface. It is possible to change the number of cathodes 23 according to the size of the substrate 1.

Each of the triangular cathodes 23 is rotated to face the side of the substrate or the side of back surface discharge. The back surface discharge is mainly used for the aging or the like of the target 24, and the film of the target 24 which is the thin film material source is attached to a shield 25 on the back surface. Since the cathode 23 is formed in the shape of a triangular prism, it is possible to perform three types of film formation at the maximum. For the substrate 1, two films can be simultaneously formed by the cathodes 23 arranged on the left and the right. A substrate tray 26 that has been transferred to the sputtering chamber 16 is stopped at a predetermined position within the sputtering chamber 16, and a movable mask 27 disposed within the sputtering chamber 16 covers the entire frame of the substrate tray 26 such that a film is prevented from adhering to members that are transferred into the sputtering chamber 16, such as the substrate tray 26 and a side clamp 28.

A front view in a state where the mask 27 is attached to the conventional substrate tray 26 is shown in FIG. 5; a cross-sectional view taken along line A-A′ of FIG. 5 indicated by arrows is shown in FIG. 6.

FIG. 5 shows a state where side clamps 28 serving as holding units make contact with the peripheral portion (the end surface) of the substrate 1 and thus the substrate in an opening portion is held. FIG. 6 shows a state where the mask 27 covers the entire frame other than the opening portion of the substrate tray 26 and the side clamp 28 such that a film is prevented from adhering thereto.

The substrate tray 26 holding the substrate 1 that has been transferred in a direction indicated by an arrow from an unillustrated substrate process chamber connected to the sputtering chamber 16 is stopped at a predetermined position within the sputtering chamber 16, and the mask 27 attached within the sputtering chamber 16 covers the entire frame of the substrate tray 26. In this way, the film is prevented from adhering to the substrate tray 26 and the side clamp 28 in the state shown in FIG. 5 or 6.

At the same time when the substrate tray 26 covers the mask 27, a gas such as Ar is introduced into the sputtering chamber 16. When the pressure within the sputtering chamber 16 reaches a predetermined film formation pressure, a predetermined voltage is applied to the side of the cathodes 23 and thus sputtering discharge is performed.

After the completion of the film formation by sputtering, the voltage applied to the side of the cathodes 23 and the gas are stopped, and thereafter the mask 27 is separated from the substrate tray 26. The substrate tray is transferred from the sputtering chamber 16 to the unillustrated substrate process chamber.

### SUMMARY OF THE INVENTION

However, although, in the conventional sputtering apparatus shown in FIG. 5 or 6, the side clamps 28 are arranged so as to be hidden by the mask 27 at the time of the film formation, sputter particles that are thin film material particles also adhere to the side clamps 28.

This is because, since the sputter particles being sputtered contain components that for example, due to collision between the sputter particles and gas molecules such as Ar, obliquely and linearly travel with respect to the normal of the surface to be processed of the substrate 1, the sputter particles traveling obliquely and linearly also adhere to the side clamps 28 that should have been covered by the mask 27. Hence, the side clamps 28 having the film adhered thereto become conductive, and an electrical breakdown is caused between the side clamps 28 and the glass substrate 1 and thus arching (abnormal discharge) is disadvantageously produced.

The film adhering to the side clamps 28 makes contact with the substrate 1, and this causes particles in which the adhered film stains the substrate 1. Furthermore, the occurrence of the arching and the particles causes electrodes serving as image display elements to be disconnected.

The side clamps 28 to which a large amount of film has adhered need to be replaced. Hence, since the sputtering apparatus is open to the atmosphere and thus the clamps having the film adhered are replaced, the productivity is disadvantageously reduced.

An object of the present invention is to provide a film forming apparatus that can reduce the adherence of thin film material particles to a holding mechanism of a substrate tray at the time of film formation.

To achieve the above object, according to one aspect of the present invention, there is provided A film forming apparatus comprising: a substrate tray which includes a substrate support surface for supporting a substrate, a support portion arranged around the substrate support surface and a holding mechanism arranged around the substrate support surface for holding the substrate, the substrate tray being configured to be detachable from the film forming apparatus and configured to be installable within the film forming apparatus such that the substrate support surface faces an upper side in a direction of gravitational force and is inclined relative to the direction of gravitational force; a movement mechanism which changes a position of the holding mechanism between when a film is formed on the substrate and when the substrate is transferred; and a mask that has an opening of a predetermined shape through which a thin film material particle from a thin film material source facing the substrate tray installed within the film forming apparatus passes, and for forming a thin film of the predetermined shape on the substrate supported by the substrate support surface, wherein: when the substrate tray is installed in the inclined state within the film forming apparatus, the support portion is formed so as to be positioned on a lower side of the substrate supported by the substrate support surface in the direction of gravitational force; when the film is formed, the mask is arranged so as to cover part of the substrate supported by the support portion, the holding mechanism and the substrate tray; and at the time of transfer, the movement mechanism moves the holding mechanism such that the holding mechanism holds the substrate, and at the time of film formation, in a region covered by the mask, the movement mechanism moves the holding mechanism from a position where the substrate is held by the holding mechanism at the time of transfer toward an outside of the substrate tray.

According to the present invention, in the substrate tray that holds and transfers the substrate, since, while the thin film is being formed, the clamp serving as the holding mechanism makes contact with the side on the lower portion of the substrate and two corner portions of both ends of the side and thereby holds the substrate, it is possible to suppress the occurrence of arching and reduce the particles.

Since the frequency of the exchange of the clamp is reduced, the frequency of the maintenance is decreased, and thus it is possible to improve the decrease in productivity.

Furthermore, since the frequency of arching and particles is reduced, for example, it is possible to reduce the disconnection of a wiring film serving as the image display element.

Further features of the present invention will become apparent from the following description of exemplary embodiments with reference to the attached drawings.

### BRIEF DESCRIPTION OF THE DRAWINGS

FIG. 1 is a front view of a substrate tray at the time of thin film formation in an embodiment of the present invention.

FIG. 2 is a cross-sectional view of the substrate tray at the time of thin film formation in an embodiment of the present invention, which shows a cross-sectional view taken along line B-B′ of FIG. 1 indicated by arrows.

FIG. 3 is a side view of the lower portion of the substrate tray at the time of thin film formation in an embodiment of the present invention.

FIG. 4 is a diagram showing the configuration of a sputtering chamber in a conventional sputtering apparatus when seen from above.

FIG. 5 is a front view in a state where a mask is attached to a conventional substrate tray.

FIG. 6 is a cross-sectional view taken along line A-A′ of FIG. 5 indicated by arrows.

FIG. 7 shows a cross-sectional structure of an a-Si TFT (thin film transistor).

FIG. 8 is a diagram showing an example of a movement mechanism for moving a holding mechanism in an embodiment of the present invention.

### DESCRIPTION OF THE EMBODIMENTS

Preferred embodiments of the present invention will now be described in detail in accordance with the accompanying drawings.

A typical embodiment of the present invention will be described below with reference to accompanying drawings. In the drawings described below, components having the same functions are identified with like reference numerals, and their description will not be repeated.

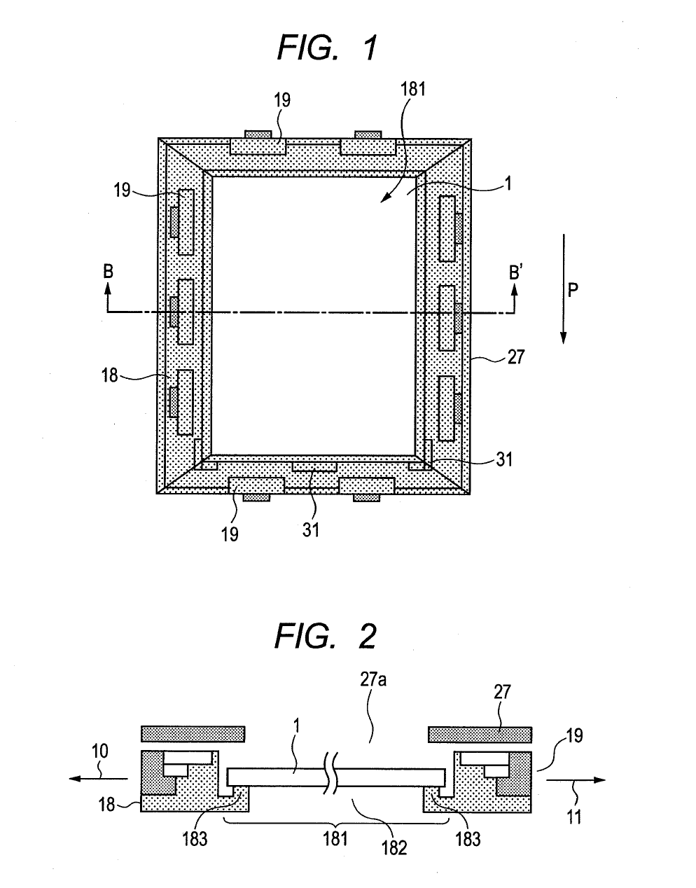

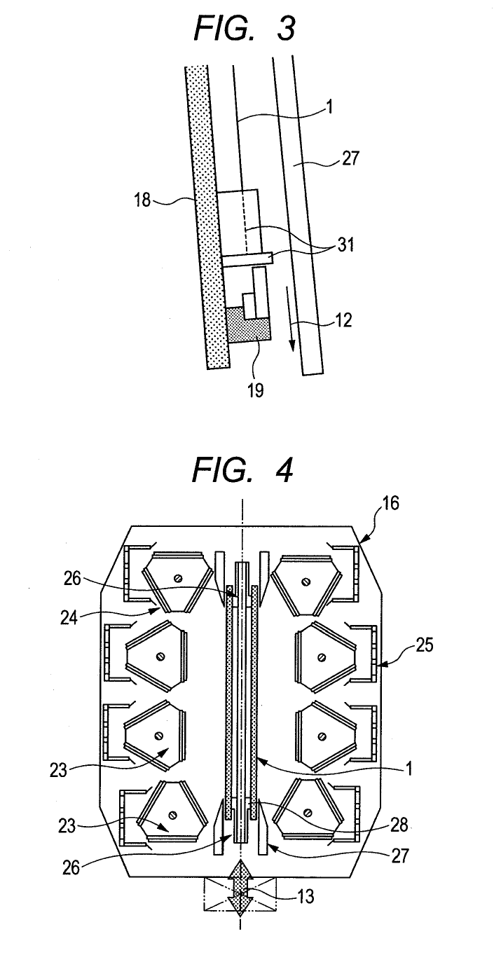

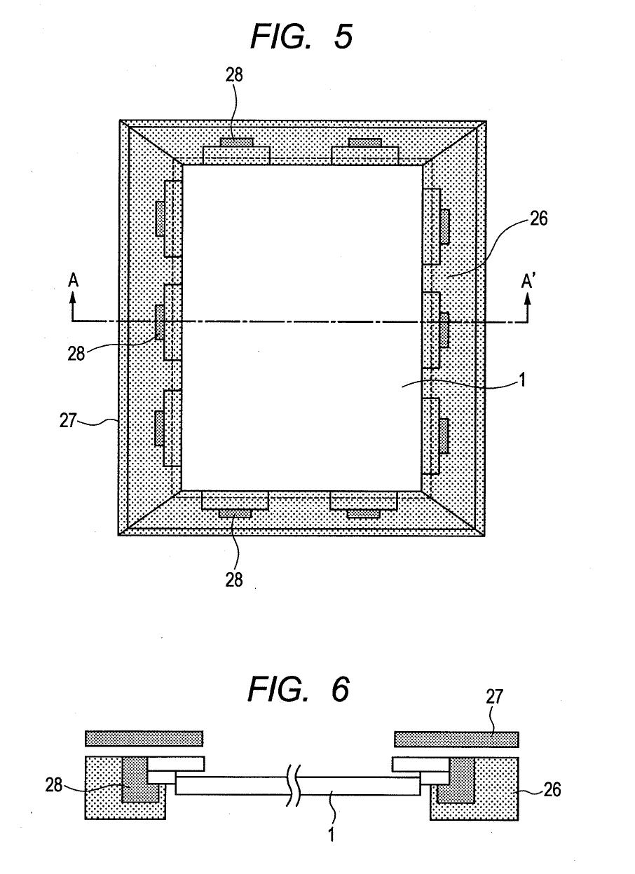

FIG. 1 is a front view of a substrate tray at the time of thin film formation in an embodiment of the present invention; FIG. 2 is a cross-sectional view taken along line B-B′ of FIG. 1 indicated by arrows; and FIG. 3 shows a side view of the lower portion of the substrate tray at the time of thin film formation.

As shown in FIGS. 1 to 3, a substrate tray 18 of the present embodiment includes a plurality of side clamps and bottom clamps 31 that function as a substrate support portion, and is configured so as to be detachable from a sputtering chamber 16 as a film forming apparatus. The side clamps 19 are a holding mechanism that holds the substrate; the plurality of side clamps 19 are arranged so as to surround a region 181 of the substrate tray 18 where the substrate 1 is disposed when the substrate tray 18 is disposed horizontally. An opening portion 182 is formed in the region 181; in the edge of the opening portion 182, a convex portion 183 is provided so as to surround the opening portion 182. With this configuration, when the substrate tray 18 is disposed horizontally, the substrate 1 can be placed on the convex portion 183.

The substrate tray 18 includes a movement mechanism (not shown in FIGS. 1 to 3) for moving the side clamps 19; the side clamps 19 can be moved by the movement mechanism in a direction (that is, in a direction toward the outside of the substrate tray 18) away from a region (that is, the region 181) where the substrate 1 is positioned on the substrate tray 18 and in a direction (that is, in a direction toward the inside of the substrate tray 18) approaching the region (that is, the region 181). Since, as described above, the side clamps 19 are configured such that they can be moved in the direction toward the outside and in the direction toward the inside, of the substrate tray 18, the substrate 1 can be supported fixedly by the side clamps 19 when the substrate tray 18 is transferred whereas the side clamps 19 can be arranged away from the substrate 1 when a thin film is formed. An example of the movement mechanism will be described later.

On the other hand, when the substrate tray 18 that is disposed horizontally is made to stand (for example, when it is disposed substantially perpendicularly), the bottom clamps 31 are arranged lower than the substrate in the direction of gravitational force. In other words, when the substrate tray 18 is disposed in the sputtering chamber 16 serving as a film formation chamber as shown in FIG. 4, the substrate tray 18 is configured such that the substrate is positioned on the bottom clamps 31. When, as described above, in case of making the substrate tray 18 stand obliquely (when the substrate tray 18 is disposed within the sputtering chamber 16), the bottom clamps 31 function as a support portion for supporting the substrate 1.

Furthermore, the substrate tray 18 is configured such that, within the film formation chamber such as the sputtering chamber 16, the substrate 1 held by the substrate tray 18 can be held to stand at a predetermined angle of inclination. In other words, the substrate tray is configured so that the substrate tray 18 can be disposed within the sputtering chamber 16 such that a state where the substrate tray 18 is inclined with a predetermined angle toward the side opposite to a support surface of the substrate tray 18 from a state where the support surface for supporting the substrate 1 is positioned parallel to the direction of gravitational force.

As described above, in the present embodiment, the substrate tray 18 is configured such that the substrate support surface of the substrate tray 18 is inclined with respect to the direction parallel to the direction of gravitational force P so as to be on the upper side in the direction of gravitational force; the bottom clamps 31 are provided such that, when the substrate support surface of the substrate tray 18 is inclined, the bottom clamps 31 are lower than the substrate 1 in the direction of gravitational force P. Therefore, even when the substrate tray 18 is disposed within the sputtering chamber 16, and the substrate 1 is not held by the side clamps 19, the substrate 1 can be held on the substrate tray 18 without falling down. In other words, with the above inclined arrangement, it is possible to make the substrate 1 lean against the substrate tray 18 (in the present embodiment, the convex portion 183) and to support, with the bottom clamps 31, a side (a lower side described later) of the substrate 1 in the direction of gravitational force P.

FIG. 1 shows a state where, when the thin film is formed, in a predetermined position within the sputtering chamber 16, the lower side of the substrate 1 and the bottom clamps 31 in contact with the two corner portions at both ends of the side hold the substrate 1 positioned in the opening portion 182 (the region 181) of the substrate tray 18. In other words, when, in FIGS. 1 and 3, the direction P indicated by the arrow is assumed to be the direction of gravitational force, the substrate tray 18 is disposed within the sputtering chamber 16 such that the substrate support surface of the substrate tray 18 is inclined with respect to the direction parallel to the direction of gravitational force P.

Here, the lower side of the substrate 1 refers to the lowermost side (the lowermost side in the direction of gravitational force P) of the substrate 1 that leans against the substrate tray 18.

The mask 27 is arranged such that, as shown in FIGS. 1 to 3, the edge region of the substrate tray 18 including the side clamps 19 and the bottom clamps 31 and a predetermined region of the substrate 1 are masked and that the surface to be processed of the substrate 1 is exposed against the cathodes 23 as the thin film material source. Specifically, as shown in FIG. 2, an opening 27a of a predetermined shape is formed in the mask 27, and sputter particles produced from targets 24 supported by the cathodes 23 are made to pass through the opening 27a, and thus it is possible to form the thin film of the predetermined shape on the substrate 1. The mask 27 is provided within the sputtering chamber 16, and has a mask drive mechanism (not shown) for changing the position of the mask 27. With this configuration, by controlling the mask drive mechanism with an unillustrated control device, it is possible to fit the mask 27 to the substrate tray 18 when the substrate tray 18 is disposed within the sputtering chamber 16. In other words, when the film is not formed, the mask 27 is held in a predetermined position within the sputtering chamber 16. When the substrate tray 18 is disposed within the sputtering chamber 16 at the time of the film formation, the control device controls the mask drive mechanism to move the mask 27 arranged in the predetermined position and can position the mask 27 such that the mask 27 covers the region (the region including the side clamps 19 and the bottom clamps 31) other than the region 181 of the substrate tray 18 and a predetermined region (the portion that is formed in the shape of the opening 27a and that exposes the substrate 1) of the substrate 1.

In the present embodiment, when the thin film is formed, a force indicated by reference numeral 10 or 11 of FIG. 2 is made to act on the side clamps 19, and thus the side clamps 19 can be slided to such a position that the side clamps 19 are completely covered by the mask 27 and that the film is prevented from adhering thereto. FIG. 3 shows a state where, when the thin film is formed, the side clamps 19 holding the lower side of the substrate 1 receives a force indicated by reference numeral 12 to slide, and only the bottom clamps 31 hold the two corner portions attached to both ends of the lower side.

In other words, the movement mechanism moves the side clamps 19 in a direction (a direction along the force 10 or 11) toward the outside of the substrate tray 18, and can arrange the side clamps 19 away from the inside edge (the edge of the substrate 1 in the direction of the center) of the mask 27 to the outside of the substrate tray 18. The outside of the substrate tray 18 is covered by the mask 27; as it further moves to the outside, it moves away from the inside edge (the portion where the substrate 1 is exposed from the cathodes 23) of the mask 27. Hence, when the side clamps 19 are arranged away from the inside edge of the mask 27 to the outside of the substrate tray 18 at the time of the film formation, the side clamps 19 are arranged in the back of the region on the substrate tray 18 covered by the mask 27. Therefore, even if the sputter particles collide with the gas molecules such as Ar and thereby enters the substrate 1 obliquely, it is possible to reduce the number of sputter particles that reach the side clamps 19.

On the other hand, when the substrate 1 is transferred by the substrate tray 18, the substrate 1 is supported by the side clamps 19 arranged around the region 181. Hence, for example, when the substrate 1 is transferred to the outside of the sputtering chamber 16 after the completion of the film formation, a force opposite to the force 10 or 11 is made to act on the side clamps 19. Thus, the side clamps 19 arranged outside the substrate tray 18 are moved in a direction toward the inside of the substrate tray 18, and are made in contact with the substrate 1, and the substrate 1 is held by the side clamps 19. As described above, the position of the side clamps 19 is changed between when the film is formed and when the substrate is transferred; thus, when the sputter particles come flying at the time of the film formation, the side clamps 19 can be arranged in the back of the region covered by the mask 27 whereas, when the substrate is transferred, the substrate 1 can be firmly held (clamped) by the side clamps 19.

In the present embodiment, as described above, when the substrate is transferred, the substrate 1 is held by the side clamps 19. When, in this state, the substrate tray 18 is disposed at a predetermined position of the sputtering chamber 16, the movement mechanism moves the side clamps 19 from the position where the substrate 1 is held by the side clamps 19 to the back (the outside of the substrate tray 18) of the region covered by the mask. The film formation operation is performed in this state, and thus it is possible to reduce the adherence of the sputter particles to the side clamps 19.

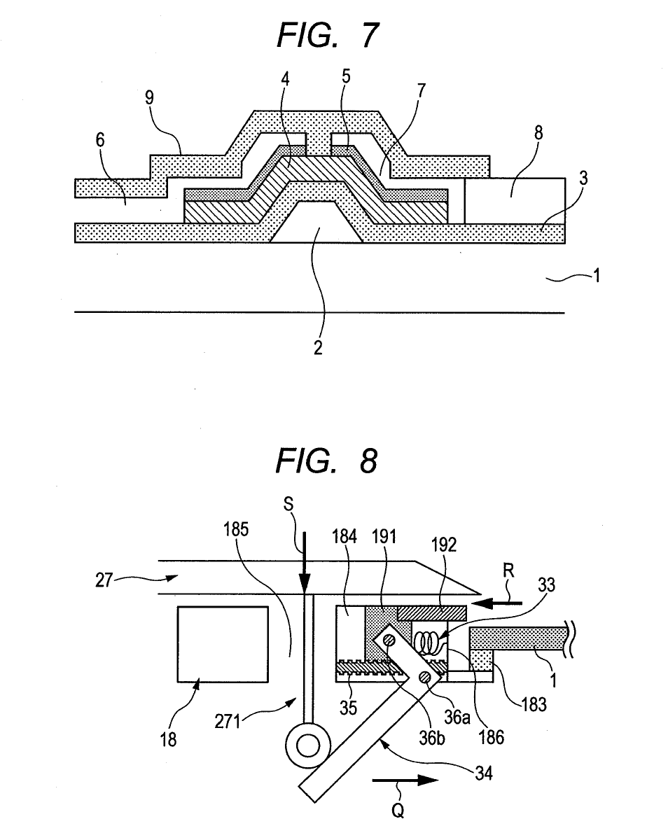

An example of the movement mechanism described above will now be described. The movement mechanism may be a mechanism in which the state of the clamp at the time of the thin film formation is interlocked with attachment of the mask 27. Specifically, when the side clamps 19 hold down the substrate 1, interlocking with attachment and detachment of the mask 27, the substrate 1 can be held down with the force of a spring connecting the side clamps 19 and the substrate tray 18. FIG. 8 is a diagram showing an example of the movement mechanism; FIG. 8 is also a diagram illustrating the movement mechanism when interlocking attachment and detachment of the mask 27 with movement of the side clamps 19.

In FIG. 8, reference numeral 191 represents a base portion of the side clamp 19, and reference numeral 192 represents a clamp portion for clamping the substrate 1. The substrate tray 18 also has a hollow portion 184. A through hole 185 is formed in the substrate tray 18.

The movement mechanism includes a spring 33, an L-shaped jig 34, a guide portion 35 for guiding the base portion 191 and pins 36a and 36b. The guide portion 35 is disposed within the hollow portion 184; one end of the spring 33 is connected to the inside wall 186 of the hollow portion 184 and the other end is connected to the base portion 191. An opening portion is formed in the inside wall 185, and the clamp portion 192 protrudes from the opening portion to the outside of the hollow portion 184. The L-shaped jig 34 is rotatably attached by the pin 36a to the bottom portion of the hollow portion 184. The L-shaped jig 34 is also rotatably attached by the pin 36b to the base portion 191. In other words, the L-shaped jig 34 is rotatably fixed to each of the bottom portion of the hollow portion 184 and the base portion 191 slidably arranged on the guide portion 35. Hence, as the L-shaped jig 34 is rotated and moved in a direction indicated by Q, the base portion 191 (the side clamp 19) can be moved in a direction indicated by R.

In the configuration shown in FIG. 8, a rod portion 271 is provided on the mask 27, and, when the mask 27 is fitted to the substrate tray 18, the rod portion 271 passes through the through hole 185 and presses the L-shaped jig 34 in a direction indicated by S.

Here, when the side clamps 19 are separated from the substrate 1 (for example, when the film is formed), as shown in FIG. 8, the rod portion 271 on the mask 27 presses the L-shaped jig 34 connected to the side clamps 19 and thus the side clamps 19 are separated. Specifically, when the control device drives the mask drive mechanism (not shown) and makes the mask 27 approach the substrate tray 18 disposed within the sputtering chamber 16, the rod portion 271 makes contact with the L-shaped jig 34 through the through hole 185, and the L-shaped jig 34 is pressed in the direction S indicated by an arrow. As the pressing allows the L-shaped jig 34 to be rotated in the direction Q indicated by an arrow, the base portion 191 moves, while extending the spring 33, along the direction R indicated by an arrow on the guide portion 35 toward the direction R indicated by the arrow. Then, when the movement of the mask 27 in the direction S indicated by the arrow is stopped by the control device, the movement of the rod portion 271 is also stopped, and the movement of the L-shaped jig 34 and the base portion 191 is also stopped. Consequently, when the film is formed, the base portion 191 and the clamp portion 192 can be retracted to the back of the region covered by the mask 27.

By contrast, when the substrate 1 is held down by the side clamps 19 (for example, when the substrate 1 is transferred), the rod portion 271 attached to the mask 27 is separated, and thus the substrate 1 is held down by the force of the spring 33 connecting the side clamps 19 and the substrate tray 18. Specifically, when the control device controls the mask drive mechanism to separate the mask 27 from the substrate tray 18, the rod portion 271 is moved in a direction opposite to the direction S indicated by the arrow, the rod portion 271 is separated from the L-shaped jig 34 and the press of the L-shaped jig 34 is released. However, in the configuration of FIG. 8, the extended spring 33 exerts resilience, the resilience causes the base portion 191 to move on the guide portion 35 to the side opposite to the direction R indicated by the arrow and this movement causes the L-shaped jig 34 to rotate to the side opposite to the direction Q indicated by the arrow. In this way, when the substrate 1 is transferred, the base portion 191 and the clamp portion 192 that are retracted at the time of the film formation are extracted, and the substrate 1 can be supported by the clamp portion 192. Here, the convex portion 183 serving as a substrate receiver is additionally attached to the substrate tray 18 at the lower portion of the clamp portion 192, and thus it is possible to hold the substrate tray 18. Since the substrate tray 18 and the substrate 1 are inclined, the substrate 1 is prevented from falling down as described above.

On the other hand, it is also possible to adopt a configuration in which, when the side clamps 19 are separated from the substrate 1 at the time of the film formation, a repulsive force (a pushing back force) of an unillustrated spring is applied to the side clamps 19 being interlocked with attachment of the mask 27, and thus the side clamps 19 are moved away from the substrate 1 (FIG. 2).

Furthermore, it may be possible to adopt a configuration in which the side clamps 19 can be electromagnetically moved (for example, a drive mechanism such as an actuator is provided, and the drive mechanism is controlled by a control device), and in which the interlocking operation can be performed via a signal for the start of discharge or a signal for the introduction of gas and an electrical signal.

Since the sneaking amount of the film also differs depending on a sputter voltage, a gas pressure and a distance between the mask and the glass substrate, it is possible to freely select, based on these conditions, the distance of the movement (slide) of the side clamp 19 for preventing the film from adhering thereto by sputtering.

In a holding state that after the completion of the film formation, the voltage and the gas on the side of the cathodes 23 are stopped, the mask 27 is simultaneously separated from the substrate tray 18 and the side clamps 19 presses the substrate 1 again, the substrate tray 18 may be transferred from the sputtering chamber 16 to the unillustrated substrate process chamber.

As an example of the actual method of producing the display element, a method of producing a liquid crystal panel using the sputtering apparatus according to the present invention will now be described with reference to FIG. 7.

FIG. 7 shows a cross-sectional structure of an a-Si TFT (thin film transistor).

In the actual method of producing the display element, the film forming apparatus is used in an array production step and a BM (black matrix) production step. For example, in the array production step, transistors and wiring are formed on the substrate 1, and sputtering for film formation is mainly used in steps a, d and e below; a to f below are sequentially stacked.

Step a. gate electrode (such as Mo or Al) 2
Step b. gate insulation film (such as SiNx) 3
Step c. semiconductor layers (such as a-Si and a-Si(n+)P) 4 and 5
Step d. source-drain electrodes (such as Mo or Al) 6 and 7
Step e. transparent electrode (such as ITO) 8
Step f. protective film (such as SiNx) 9

In the cross-sectional structure of the TFT shown in FIG. 7, in each of the steps a, d and e, according to the type of target that is a thin film material source, parameters such as a sputtering gas, the degree of vacuum, the temperature of the substrate, a discharge power and a discharge time were adjusted, and thus a thin film suitable for the display element was successfully formed. Furthermore, with the substrate tray of the present invention, the frequency of the arching and the particle was successfully reduced, and the disconnection of the wiring film of the element was successfully reduced.

While the present invention has been described with reference to exemplary embodiments, it is to be understood that the invention is not limited to the disclosed exemplary embodiments. The scope of the following claims is to be accorded the broadest interpretation so as to encompass all such modifications and equivalent structures and functions.

1. A film forming apparatus comprising:
a substrate tray which includes a first support surface portion for supporting a substrate, a second support portion arranged around the first support portion and a holding portion arranged around the first support portion for holding the substrate, the substrate tray being configured to be detachable from the film forming apparatus and configured to be installable within the film forming apparatus such that the first support portion faces an upper side in a direction of gravitational force and is inclined relative to the direction of gravitational force;
a movement means for changing a position of the holding portion between when a film is formed on the substrate and when the substrate is transferred; and
a mask that has an opening of a predetermined shape through which a thin film material particle from a thin film material source facing the substrate tray installed within the film forming apparatus passes, and for forming a thin film of the predetermined shape on the substrate supported by the first support portion, wherein:
when the substrate tray is installed in the inclined state within the film forming apparatus, the second support portion is formed so as to be positioned on a lower side of the substrate supported by the first support portion in the direction of gravitational force;
when the film is formed, the mask is arranged so as to cover part of the substrate supported by the second support portion, the holding portion and the substrate tray; and
at the time of transfer, the movement means moves the holding portion such that the holding portion holds the substrate, and at the time of film formation, in a region covered by the mask, the movement means moves the holding portion from a position where the substrate is held by the holding portion at the time of transfer toward an outside of the substrate tray.

2. The film forming apparatus according to claim 1, wherein the movement means is configured to perform arrangement of the mask and operation of moving the holding portion from the position where the substrate is held toward the outside of the substrate tray in an interlocking manner.

3. The film forming apparatus according to claim 1, wherein when the substrate tray is installed within the film forming apparatus in the inclined state, the second support portion makes a contact with a side on the lower side of the substrate supported by the first support portion in the direction of gravitational force and two corner portions at both ends of the side.

4. The film forming apparatus, wherein the film forming apparatus according to claim 1 is a sputtering apparatus.
